(19) United States
(12) Patent Application Publication
(10) Pub. No.: US 2026/0190400 A1
(43) Pub. Date: Jul. 2, 2026

(54) SEMICONDUCTOR DEVICE

(71) Applicant: Samsung Electronics Co., Ltd., Suwon-si (KR)

(72) Inventors: Jae-Hyun Yoo, Suwon-si (KR); Dawon Jeong, Suwon-si (KR); Hiroki Fujii, Suwon-si (KR); Yonghee Park, Suwon-si (KR); Kunsik Sung, Suwon-si (KR)

(21) Appl. No.: 19/290,040

(22) Filed: Aug. 4, 2025

(30) Foreign Application Priority Data
Dec. 27, 2024 (KR) 10-2024-0198778

(51) Int. Cl. H10D 62/10; H10D 30/01; H10D 62/60; H10D 64/27; H10D 64/68

(52) U.S. Cl. CPC H10D 62/102; H10D 62/60; H10D 64/513; H10D 64/516; H10D 64/518; H10D 64/685; H10D 30/027

(57) ABSTRACT

A semiconductor device includes: a well region of a first conductivity type in a substrate; a first doping region and a second doping region of a second conductivity type on the well region; a first source/drain region on the first doping region and a second source/drain region on the second doping region; a gate insulation layer including a first gate insulation pattern that covers a sidewall of a recess defined between the first doping region and the second doping region and a second gate insulation pattern on the first gate insulation pattern; a gate electrode on the gate insulation layer; and a channel region below the gate insulation layer.

### CROSS-REFERENCE TO RELATED APPLICATION

This application claims priority to and the benefit of Korean Patent Application No. 10-2024-0198778 filed with the Korean Intellectual Property Office on Dec. 27, 2024, the entire contents of which are incorporated herein by reference.

### BACKGROUND

As the demand for high performance and multi-functionality of a semiconductor device increases, integration of the device is continuously increasing. Accordingly, it may be desired to design each component to operate stably within a miniaturized semiconductor device.

### SUMMARY

As semiconductor device becomes more integrated, a structural improvement may be desired to minimize electrical interference between adjacent components. To ensure the characteristics of various devices, including high-voltage semiconductor devices, appropriate electrical isolation technology may be desired.

Implementations of the present disclosure are intended to provide a highly reliable semiconductor device.

In addition, implementations of the present disclosure are intended to provide a semiconductor device for a high voltage.

An aspect of the present disclosure provides a semiconductor device including: a well region of a first conductivity type in a substrate; a first doping region of a second conductivity type and a second doping region of the second conductivity type, the first doping region and the second doping region being on the well region; a first source/drain region on the first doping region and a second source/drain region on the second doping region; a gate insulation layer including (i) a first gate insulation pattern that covers a sidewall of a recess defined between the first doping region and the second doping region and (ii) a second gate insulation pattern on the first gate insulation pattern; a gate electrode on the gate insulation layer; and a channel region below the gate insulation layer.

In addition, another aspect of the present disclosure provides a semiconductor device including: a well region of a first conductivity type at a substrate; a first doping region of a second conductivity type and a second doping region of the second conductivity type, the first doping region and the second doping region being on the well region; a first source/drain region on the first doping region and a second source/drain region on the second doping region; a gate insulation layer including (i) a first gate insulation pattern that covers a sidewall of a recess defined between the first doping region and the second doping region and (ii) a second gate insulation pattern on the first gate insulation pattern; a gate electrode on the gate insulation layer and overlapping (i) an upper surface of the first doping region and (ii) an upper surface of the second doping region; a channel region below the gate insulation layer; and a first spacer at a first side of the gate electrode and on the second gate insulation pattern, and a second spacer at a second side of the gate electrode and on the second gate insulation pattern.

In addition, another aspect of the present disclosure provides a semiconductor device including: a well region of a first conductivity type in a substrate; a first doping region and a second doping region of a second conductivity type on the well region; a first source/drain region on the first doping region and a second source/drain region on the second doping region; a gate insulation layer including (i) a first gate insulation pattern that covers a sidewall of a recess defined between the first doping region and the second doping region and (ii) a second gate insulation pattern on the first gate insulation pattern; a gate electrode on the gate insulation layer and overlapping (i) an upper surface of the first doping region and (ii) an upper surface of the second doping region; a channel region below the gate insulation layer; and a first spacer at a first side of the gate electrode and on the second gate insulation pattern, and a second spacer at a second side of the gate electrode and on the second gate insulation pattern.

In addition, another aspect of the present disclosure provides a manufacturing method of a semiconductor device. The manufacturing method includes: forming a well region of a first conductive type in a substrate; forming a doping region of a second conductivity type on the well region; forming a recess on the doping region; forming a channel region on the well region by doping an impurity on a bottom surface of the recess; forming a first gate insulating material layer on the doping region and in the recess; exposing the first channel region by removing a part of the first gate insulating material layer; forming a second gate insulating material layer on the first gate insulating material layer and the channel region; forming a gate electrode material layer on the second gate insulating material layer; patterning the gate electrode material layer; exposing at least a part of an upper surface of the doping region by patterning the first gate insulating material layer and the second gate insulating material layer; and forming a source/drain region on the doping region.

In some implementations, after the patterning the gate electrode material layer, the manufacturing method may further include forming a spacer on opposite sides of a gate electrode formed by patterning the gate electrode material layer.

In some implementations, after the exposing the channel region by removing the part of the first gate insulating material layer, the first gate insulating material layer may not overlap the channel region.

In some implementations, after the forming the first gate insulating material layer on the doping region and in the recess, the manufacturing method may further include forming an intermediate insulating material layer and patterning the intermediate insulating material layer.

In some implementations, the intermediate insulating material layer may include a material that is different from a material of the first gate insulating material layer and a material of the second gate insulating material layer.

In some implementations, the first gate insulating material layer and the second gate insulating material layer may include the same material.

In some implementations, a device isolation layer may further be included in the substrate, and in the forming the doping region on the well region, the doping region may be formed to cover one side surface and at least a part of a bottom surface of the device isolation layer.

In some implementations, the channel region is of the first conductivity type, and a doping concentration of the channel region may be higher than a doping concentration of the well region.

In some implementations, in the forming the channel region on the well region through the recess, the channel region is formed such that the doping region may be divided into a first doping region and a second doping region.

In some implementations, the source/drain region is of the second conductivity type, and a doping concentration of the source/drain region may be higher than a doping concentration of the doping region.

According to the implementations of the present disclosure, a highly reliable semiconductor device can be provided.

In addition, according to implementations of the present disclosure, a semiconductor device for a high voltage can be provided.

### BRIEF DESCRIPTION OF THE DRAWINGS

FIG. 1 is a cross-sectional view of an example of a semiconductor device.

FIG. 2 to FIG. 8 are cross-sectional views of examples of semiconductor device.

FIG. 9 to FIG. 22 are diagrams illustrating the process steps involved in manufacturing an example semiconductor device.

### DETAILED DESCRIPTION

Hereinafter, various examples of the present disclosure will be described in detail with reference to the attached drawings such that a person having ordinary skill in the art to which the present disclosure pertains can easily implement the invention. The present disclosure may be implemented in many different forms and is not limited to the examples described herein.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to be positioned above or below the target element, and will not necessarily be understood to be positioned “at an upper side” based on an opposite to gravity direction.

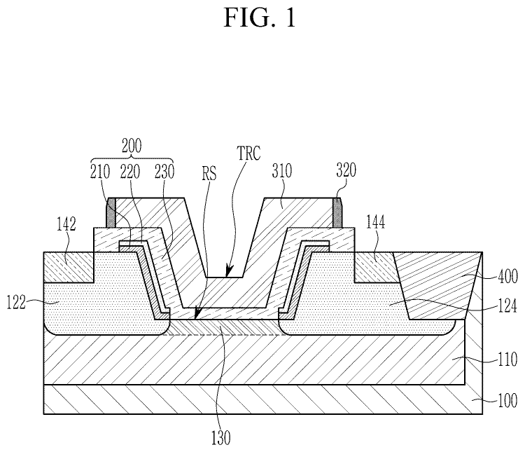

FIG. 1 is a cross-sectional view of an example of a semiconductor device.

Referring to FIG. 1, a semiconductor device according to an example may include a substrate 100, a well region 110, a first doping region 122, a second doping region 124, a channel region 130, a first source/drain region 142, a second source/drain region 144, a gate insulation layer 200, and a gate electrode 310.

The substrate 100 may be, for example, a bulk silicon or a silicon-on-insulator (SOI). In some examples, the substrate 100 may be a silicon substrate, or may include other materials such as, for example, silicon germanium (SiGe), indium antimony (InSb), a lead tellurium (PbTe) compound, indium arsenic (InAs), indium phosphide (InP), gallium arsenic (GaAs), or gallium antimony (GaSb).

Alternatively, the substrate 100 may be an epitaxial layer formed on a base substrate. In this case, the epitaxial layer may contain an elemental semiconductor material such as silicon (Si) or germanium (Ge). In addition, the epitaxial layer may include a compound semiconductor, for example, a group IV-IV compound semiconductor or a group III-V compound semiconductor.

Specifically, taking the group IV-IV compound semiconductor as an example, the epitaxial layer may be a binary compound or a ternary compound containing at least two or more of carbon (C), silicon (Si), germanium (Ge), and tin (Sn), or the binary compound or ternary compound doped with the group IV element.

For example, in the case of a III-V compound semiconductor, the epitaxial layer may be a binary compound, a ternary compound, or a quaternary compound formed by combining at least one of aluminum (Al), gallium (Ga), and indium (In) as a group III element with one of phosphorus (P), arsenic (As), and antimonium (Sb) as a group V element.

In some examples, the substrate 100 may be an N-type substrate. In some examples, the substrate 100 may be a P-type substrate, or an undoped substrate.

The well region 110 may be disposed in the substrate 100. The well region 110 may be disposed on the substrate 100. For example, the well region 110 may be formed by impurity-doping the substrate 100. The well region 110 may be formed by doping with impurity having a first conductivity type.

The well region 110 may be of a first conductivity type. For example, the conductivity type of the well region 110 may be P-type. When the conductivity type of the well region 110 is P-type, the well region 110 may be formed by doping the substrate 100 with a group III material. In some implementations, the conductivity type of the well region 110 may be N-type. In addition, when the conductivity type of the well region 110 is N-type, the well region 110 may be formed by doping the substrate 100 with a group V material.

The first doping region 122 and the second doping region 124 may be disposed in the substrate 100. The first doping region 122 and the second doping region 124 may be disposed on the well region 110. Bottom surfaces of the first doping region 122 and the second doping region 124 may be disposed to be in contact with the well region 110. The first doping region 122 and the second doping region 124 may be disposed to be spaced apart from each other by a certain distance. The bottom surface and at least a part of side surfaces of the first doping region 122 and the second doping region 124 may be surrounded by the well region 110.

The first doping region 122 and the second doping region 124 may be formed by doping an impurity onto the well region 110.

The first doping region 122 and the second doping region 124 may be of second conductivity types. For example, when the conductivity type of the well region 110 is P-type, the conductivity types of the first doping region 122 and the second doping region 124 may be N-type. In some implementations,, when the conductivity type of the well region 110 is N-type, the conductivity types of the first doping region 122 and the second doping region 124 may be P-type.

The channel region 130 may be disposed in the substrate 100. The channel region 130 may be disposed on the well region 110. The channel region 130 may be disposed between the first doping region 122 and the second doping region 124. The channel region 130 may be disposed below a gate insulation layer 200, which will be described later. The first doping region 122 and the second doping region 124 may be disposed at opposite sides of the channel region 130. The channel region 130 may be disposed to contact the first doping region 122 and the second doping region 124.

For example, the channel region 130 may be formed by doping an impurity onto the well region 110.

The channel region 130 may be of the first conductivity type. For example, when the conductivity type of the well region 110 is P-type, the conductivity type of the channel region 130 may be P-type. In some implementations, when the conductivity type of the well region 110 is N-type, the conductivity type of the channel region 130 may be N-type. The doping concentration of the channel region 130 may be higher than the doping concentration of the well region 110. When the first conductivity type impurity doping concentration of the channel region 130 is formed relatively high, the effect of reducing leakage current may be expected.

The first source/drain region 142 and the second source/drain region 144 may be disposed in the substrate 100. The first source/drain region 142 and the second source/drain region 144 may be disposed on the well region 110. The first source/drain region 142 may be disposed on the first doping region 122. The second source/drain region 144 may be disposed on the second doping region 124. A bottom surface and at least a part of a side surface of the first source/drain region 142 may be surrounded by the first doping region 122. A bottom surface and at least a part of a side surface of the second source/drain region 144 may be surrounded by the second doping region 124.

The first source/drain region 142 may be formed by doping an impurity onto the first doping region 122. The second source/drain region 144 may be formed by doping an impurity onto the second doping region 124. A doping concentration of the first source/drain region 142 may be higher than a doping concentration of the first doping region 122. A doping concentration of the second source/drain region 144 may be higher than a doping concentration of the second doping region 124.

The first source/drain region 142 and the second source/drain region 144 may be of a second conductivity type. For example, when the conductivity types of the first doping region 122 and the second doping region 124 are the N-type, the conductivity types of the first source/drain region 142 and the second source/drain region 144 may be the N-type. In some implementations, when the conductivity types of the first doping region 122 and the second doping region 124 are the P-type, the conductivity types of the first source/drain region 142 and the second source/drain region 144 may be the P-type.

A recess RS may be disposed on the substrate 100. The recess RS may be disposed between the first doping region 122 and the second doping region 124. The recess RS may be disposed between the first source/drain region 142 and the second source/drain region 144. The recess RS may be disposed on the well region 110. The recess RS may be disposed on the channel region 130. An upper surface of the channel region 130 may be exposed by the recess RS. The recess RS may also be disposed on a part of the first doping region 122 and a part of the second doping region 124. Sidewalls of the recess RS may be disposed on the first doping region 122 and the second doping region 124. A part of a bottom of the recess RS may be disposed on the first doping region 122 and the second doping region 124. The sidewall of the recess RS may be perpendicular to the upper surface of the substrate 100, or may be inclined at a selected angle from the upper surface of the substrate 100.

The gate insulation layer 200 may be disposed in the recess RS. The gate insulation layer 200 may be disposed on the channel region 130. At least a part of the gate insulation layer 200 may be disposed on the first doping region 122 and the second doping region 124. The gate insulation layer 200 may be disposed on the sidewall of the recess RS. The gate insulation layer 200 may extend from the sidewall of the recess RS and thus may cover at least a part of the first doping region 122 and at least a part of the second doping region 124.

The gate insulation layer 200 may include a first gate insulation pattern 210, a intermediate insulation pattern 220, and a second gate insulation pattern 230.

The first gate insulation pattern 210 may cover at least a part of a bottom surface of the recess RS. In some implementations, the first gate insulation pattern 210 may be disposed so as not to cover the bottom surface of the recess RS. For example, the first gate insulation pattern 210 may be disposed not to overlap the upper surface of the channel region 130. In some implementations, the first gate insulation pattern 210 may be disposed to be at least partially overlapped with an upper surface of the channel region 130. The first gate insulation pattern 210 may be disposed so as not to overlap a center portion of the bottom surface of the recess RS. The first gate insulation pattern 210 may be offset from a center portion of the bottom surface of the recess RS.

The first gate insulation pattern 210 may cover a sidewall of the recess RS. The first gate insulation pattern 210 may be in contact with the first doping region 122 and the second doping region 124. The first gate insulation pattern 210 may cover a side wall of the first doping region 122 and a side wall of the second doping region 124.

The first gate insulation pattern 210 may cover at least a part of an upper surface of the first doping region 122 and at least a part of an upper surface of the second doping region 124. In some implementations, the first gate insulation pattern 210 may not cover the upper surface of the first doping region 122 and the upper surface of the second doping region 124.

The intermediate insulation pattern 220 may be disposed in the recess RS. The intermediate insulation pattern 220 may be disposed on the first gate insulation pattern 210. The intermediate insulation pattern 220 may cover at least a part of the first gate insulation pattern 210. The intermediate insulation pattern 220 may be disposed between the first gate insulation pattern 210 and the second gate insulation pattern 230.

The intermediate insulation pattern 220 may be disposed on at least a part of the bottom surface of the recess RS. The intermediate insulation pattern 220 may be disposed not to overlap the upper surface of the channel region 130. In some implementations, the intermediate insulation pattern 220 may be disposed to be at least partially overlapped with the upper surface of the channel region 130. The intermediate insulation pattern 220 may be offset from the upper surface of the channel region 130.

The intermediate insulation pattern 220 may be disposed on the sidewall of the recess RS. The intermediate insulation pattern 220 may be disposed on the sidewall of the first doping region 122 and the sidewall of the second doping region 124. The first gate insulation pattern 210 may be disposed between the intermediate insulation pattern 220 and the sidewall of the recess RS. The first gate insulation pattern 210 may be disposed between the intermediate insulation pattern 220 and the first doping region 122. The first gate insulation pattern 210 may be disposed between the intermediate insulation pattern 220 and the second doping region 124.

The intermediate insulation pattern 220 may be disposed on the upper surface of the first doping region 122 and the upper surface of the second doping region 124. In some implementations, the intermediate insulation pattern 220 may not be disposed on the upper surface of the first doping region 122 and the upper surface of the second doping region 124.

The second gate insulation pattern 230 may be disposed on the first gate insulation pattern 210 and the intermediate insulation pattern 220. The second gate insulation pattern 230 may be disposed in the recess RS.

The second gate insulation pattern 230 may cover the bottom surface of the recess RS. The second gate insulation pattern 230 may be disposed on the channel region 130. The second gate insulation pattern 230 may be in contact with the channel region 130. The second gate insulation pattern 230 may cover at least a part of the upper surface of the channel region 130.

The second gate insulation pattern 230 may be disposed on the upper surface of the first doping region 122 and the upper surface of the second doping region 124.

The second gate insulation pattern 230 may be disposed on the sidewall of the recess RS. The second gate insulation pattern 230 may be disposed on the sidewall of the first doping region 122 and the sidewall of the second doping region 124. At least one of the first gate insulation pattern 210 and the intermediate insulation pattern 220 may be disposed between the second gate insulation pattern 230 and the sidewall of the recess RS. At least one of the first gate insulation pattern 210 and the intermediate insulation pattern 220 may be disposed between the second gate insulation pattern 230 and the sidewall of the first doping region 122. At least one of the first gate insulation pattern 210 and the intermediate insulation pattern 220 may be disposed between the second gate insulation pattern 230 and the sidewall of the second doping region 124.

The first gate insulation pattern 210, the intermediate insulation pattern 220, and the second gate insulation pattern 230 may include insulating materials. For example, the first gate insulation pattern 210 and the second gate insulation pattern 230 may include the same material. In addition, for example, the intermediate insulation pattern 220 may include a material that is different from the material of the first gate insulation pattern 210 and the second gate insulation pattern 230. For example, the first gate insulation pattern 210, the intermediate insulation pattern 220, and the second gate insulation pattern 230 may include at least one of silicon oxide (SiO), silicon nitride (SiN), and silicon oxynitride (SiON). In some examples, the first gate insulation pattern 210 and the second gate insulation pattern 230 may include silicon oxide (SiO), and the intermediate insulation pattern 220 may include silicon nitride (SiN).

For example, the first gate insulation pattern 210, the intermediate insulation pattern 220, and the second gate insulation pattern 230 may be disposed on the sidewall of the recess RS, and the second gate insulation pattern 230 may be disposed on the upper surface of the channel region 130. That is, a thickness of a part of the gate insulation layer 200 disposed on the sidewall of the recess RS may be greater than a thickness of a part of the gate insulation layer 200 disposed on the bottom surface of the recess RS.

The gate electrode 310 may be disposed on the gate insulation layer 200. The gate electrode 310 may be disposed on the second gate insulation pattern 230. The gate electrode 310 may be disposed in the recess RS. The gate electrode 310 may also be disposed on the first doping region 122 and the second doping region 124. The gate electrode 310 may be disposed to be spaced apart from the first source/drain region 142 and the second source/drain region 144.

The gate electrode 310 may be disposed on the channel region 130. The gate electrode 310 may be disposed on the bottom surface of the recess RS. The gate insulation layer 200 may be disposed between the gate electrode 310 and the channel region 130. Specifically, the second gate insulation pattern 230 may be disposed between the gate electrode 310 and the channel region 130.

The gate electrode 310 may be disposed on the sidewall of the recess RS. The gate insulation layer 200 may be disposed between the gate electrode 310 and the sidewall of the recess RS. At least one of the first gate insulation pattern 210, the intermediate insulation pattern 220, and the second gate insulation pattern 230 may be disposed between the gate electrode 310 and the recess RS. The gate electrode 310 may be disposed on the sidewall of the first doping region 122 and the sidewall of the second doping region 124. The gate insulation layer 200 may be disposed between the gate electrode 310 and the sidewalls of the first doping region 122 and second doping region 124. At least one of the first gate insulation pattern 210, the intermediate insulation pattern 220, and the second gate insulation pattern 230 may be disposed between the gate electrode 310 and the sidewall of the first doping region 122. At least one of the first gate insulation pattern 210, the intermediate insulation pattern 220, and the second gate insulation pattern 230 may be disposed between the gate electrode 310 and the sidewall of the second doping region 124.

The gate electrode 310 may be disposed on the upper surface of the first doping region 122 and the upper surface of the second doping region 124. In some implementations, the gate electrode 310 may not be disposed on the upper surface of the first doping region 122 and the upper surface of the second doping region 124.

A trench TRC, which is an empty space, may be formed in a center of the gate electrode 310. In some examples, the trench TRC may not be formed in the gate electrode 310. In some implementations, a spacer 320 may be additionally disposed within the trench TRC of the gate electrode 310.

The gate electrode 310 may include a conductive material. For example, the gate electrode 310 may include doped-polysilicon. Alternatively, the gate electrode 310 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. The gate electrode 310 may include a conductive metal oxide, conductive metal oxynitride, and the like, and may include the material described above in an oxidized form.

The semiconductor device according to an example may further include a spacer 320 and a device isolation layer 400.

The spacer 320 may be disposed at opposite sides of the gate electrode 310. The spacer 320 may be disposed on the gate insulation layer 200. In some implementations, the position of the spacer 320 may be changed in various ways.

The spacer 320 may include an insulating material. The spacer 320 may include, for example, at least one of silicon oxide (SiO), silicon nitride (SiN), silicon oxynitride (SiON), silicon oxycarbonitride (SiOCN), silicon boronnitride (SiBN), silicon oxyboronnitride (SiOBN), silicon carbide (SiOC), and a combination thereof.

The device isolation layer 400 may be disposed in the substrate 100. The device isolation layer 400 may be disposed on the well region 110. The device isolation layer 400 may be disposed at one side of the well region 110. The device isolation layer 400 may be disposed at one side of the second doping region 124. One side surface of the device isolation layer 400 and at least a part of the bottom surface may be covered by the second doping region 124. One side surface of the device isolation layer 400 may contact the second source/drain region 144. In some implementations, the device isolation layer 400 is provided to separate elements from each other and may be formed through a shallow trench isolation (STI) process and the like.

The device isolation layer 400 may include an insulating material. The device isolation layer 400 may include at least one of silicon oxide (SiO), silicon nitride (SiN), silicon oxynitride (SiON), silicon oxycarbonitride (SiOCN), silicon boronitride (SiBN), silicon oxyboronitride (SiOBN), silicon oxycarbide (SiOC), and a combination thereof.

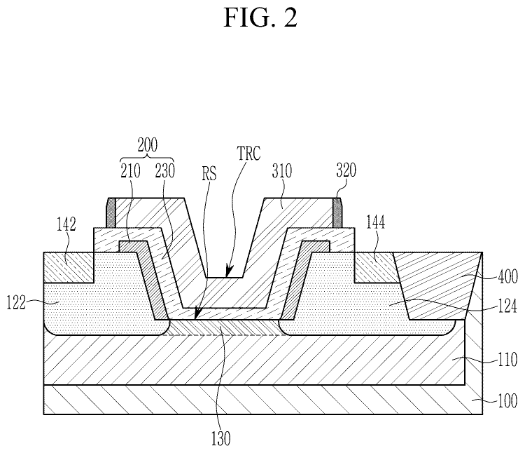

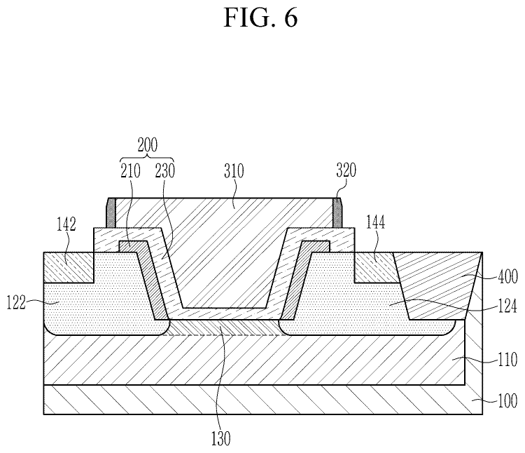

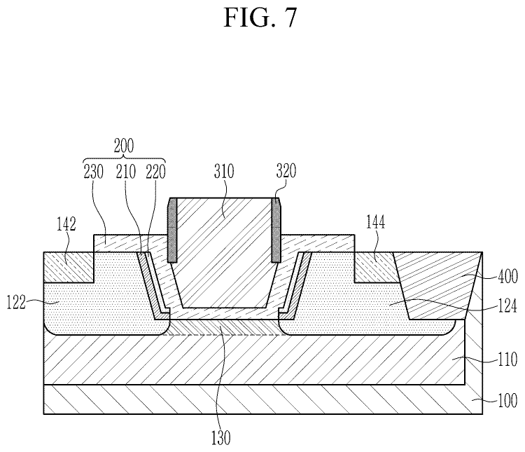

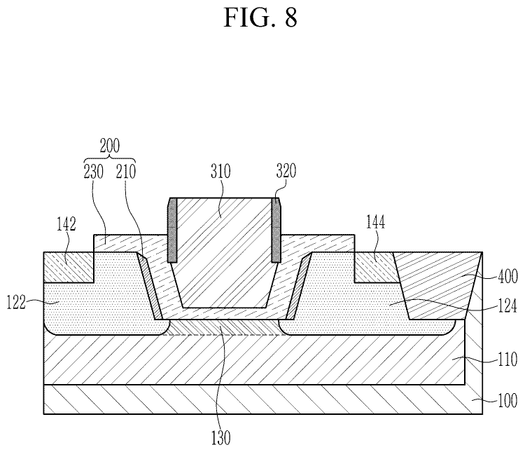

FIG. 2 to FIG. 8 are cross-sectional views of examples of semiconductor device. Among the examples of FIG. 2 to FIG. 8, descriptions of parts that are substantially the same as the example of FIG. 1 are omitted, and differences will be mainly described.

Referring to FIG. 2, a gate insulation layer 200 of a semiconductor device according to an example may include a first gate insulation pattern 210 and a second gate insulation pattern 230. In some examples, the gate insulation layer 200 may not include an intermediate insulation pattern 220.

A second gate insulation pattern 230 may be disposed on a channel region 130. The first gate insulation pattern 210 and the second gate insulation pattern 230 may be disposed on side walls of a recess RS. The first gate insulation pattern 210 and the second gate insulation pattern 230 may be disposed on a side wall of a first doping region 122 and a sidewall of a second doping region 124. The first gate insulation pattern 210 and the second gate insulation pattern 230 may be disposed between the sidewall of the recess RS and a gate electrode 310. The first gate insulation pattern 210 and the second gate insulation pattern 230 may be disposed between the sidewalls of the first doping region 122 and second doping region 124 and the gate electrode 310.

The first gate insulation pattern 210 may be disposed not to overlap an upper surface of the channel region 130.

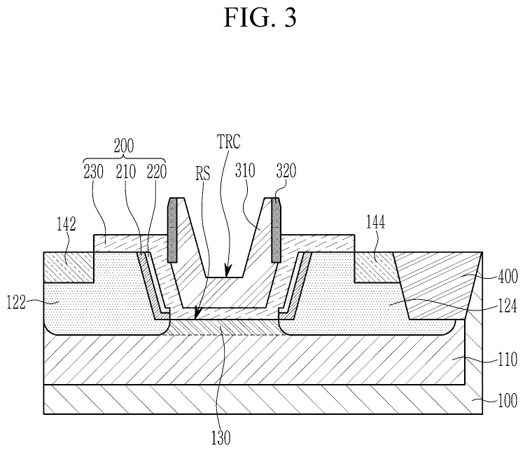

Referring to FIG. 3, a gate insulation layer 200 of a semiconductor device according to an example may include a first gate insulation pattern 210, an intermediate insulation pattern 220, and a second gate insulation pattern 230.

The second gate insulation pattern 230 may be disposed on a channel region 130. The first gate insulation pattern 210, the intermediate insulation pattern 220, and the second gate insulation pattern 230 may be disposed on a sidewall of a recess RS. The first gate insulation pattern 210, the intermediate insulation pattern 220, and the second gate insulation pattern 230 may be disposed on a sidewall of a first doping region 122 and a sidewall of a second doping region 124.

The first gate insulation pattern 210 and the intermediate insulation pattern 220 may be disposed not to overlap an upper surface of the channel region 130. The first gate insulation pattern 210 and the intermediate insulation pattern 220 may be disposed on a bottom surface of the recess RS. The first gate insulation pattern 210 and the intermediate insulation pattern 220 may not be disposed on an upper surface of the first doping region 122 and an upper surface of the second doping region 124. The second gate insulation pattern 230 may be disposed on the upper surface of the first doping region 122 and the upper surface of the second doping region 124.

The gate electrode 310 may be disposed on the channel region 130. The gate electrode 310 may not be disposed on the upper surface of the first doping region 122 and the upper surface of the second doping region 124. On opposite sides of the gate electrode 310, grooves may be disposed into which spacers 320 can be placed.

The spacer 320 may be disposed at opposite sides of the gate electrode 310. The spacer 320 may be disposed between the gate insulation layer 200 and the gate electrode 310.

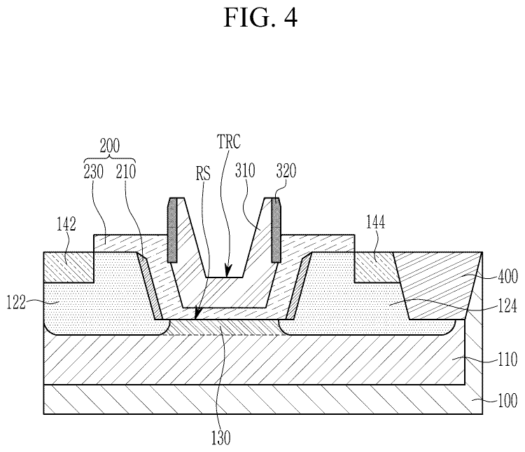

Referring to FIG. 4, a gate insulation layer 200 of a semiconductor device according to an example may include a first gate insulation pattern 210 and a second gate insulation pattern 230. In some examples, the gate insulation layer 200 may not include an intermediate insulation pattern 220.

The second gate insulation pattern 230 may be disposed on the channel region 130. The first gate insulation pattern 210 and the second gate insulation pattern 230 may be disposed on a sidewall of a recess RS. The first gate insulation pattern 210 and the second gate insulation pattern 230 may be disposed on a sidewall of a first doping region 122 and a sidewall of a second doping region 124. The first gate insulation pattern 210 and the second gate insulation pattern 230 may be disposed between the sidewall of the recess RS and the gate electrode 310. The first gate insulation pattern 210 and second gate insulation pattern 230 may be disposed between the sidewalls of the first doping region 122 and second doping region 124 and the gate electrode 310.

The first gate insulation pattern 210 may be disposed not to overlap an upper surface of the channel region 130.

The first gate insulation pattern 210 may not be disposed on an upper surface of the first doping region 122 and an upper surface of the second doping region 124. The second gate insulation pattern 230 may be disposed on the upper surface of the first doping region 122 and the upper surface of the second doping region 124.

The gate electrode 310 may not be disposed on the upper surface of the first doping region 122 and the upper surface of the second doping region 124. On opposite sides of the gate electrode 310, grooves may be disposed into which spacers 320 can be placed.

The spacer 320 may be disposed at opposite sides of the gate electrode 310. The spacer 320 may be disposed between the gate insulation layer 200 and the gate electrode 310.

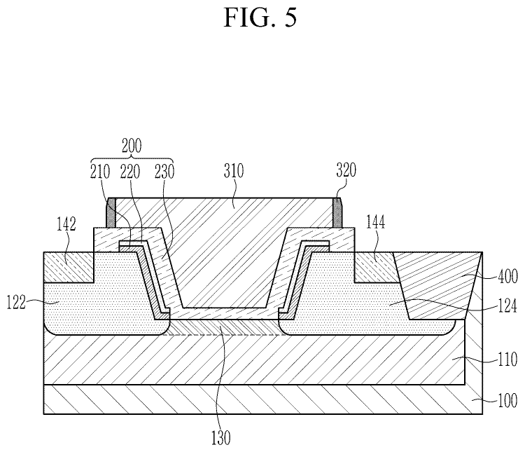

Referring to FIG. 5 to FIG. 8, a trench TRC, which is an empty space, may be formed in a center of the gate electrode 310. That is, the gate electrode 310 may fill the recess RS without any empty space inside.

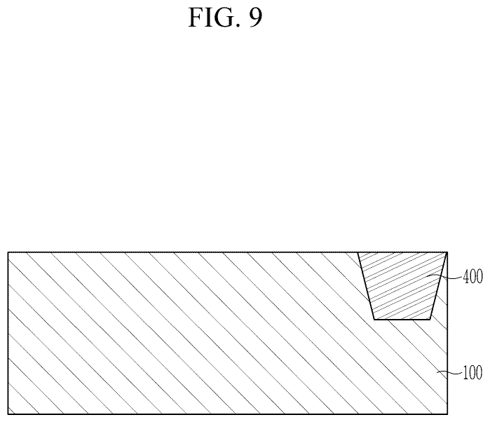

FIG. 9 to FIG. 22 are provided for description of a manufacturing method of a semiconductor device according to an example.

Referring to FIG. 9, the device isolation layer 400 may be disposed in the substrate 100. The device isolation layer 400 may be disposed on the substrate 100. The device isolation layer 400 may be formed through a shallow trench isolation (STI) process and the like.

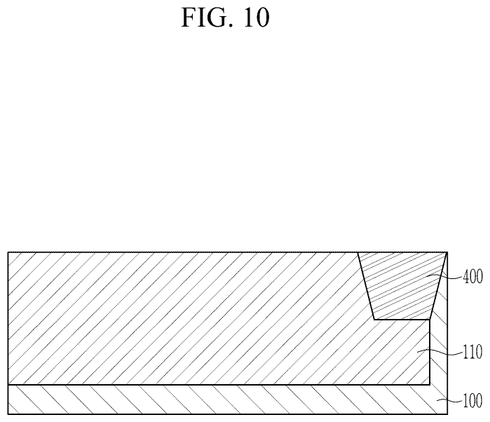

Next, referring to FIG. 10, the well region 110 may be formed in the substrate 100. The well region 110 may be disposed on the substrate 100. The well region 110 may contact at least a part of one side surface and a bottom surface of the device isolation layer 400.

The well region 110 may be formed by doping the substrate 100 with an impurity. The well region 110 may be of a first conductivity type. The well region 110 may be formed by doping with impurity having a first conductivity type on the substrate 110.

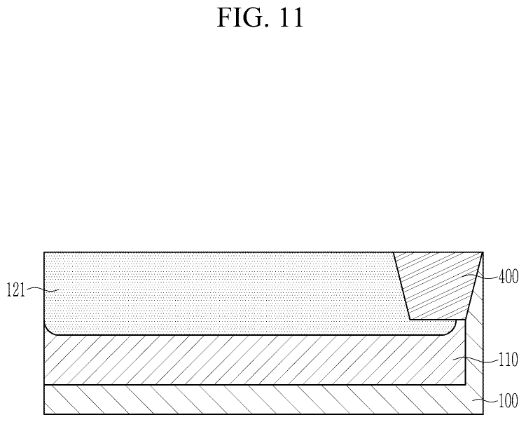

Next, referring to FIG. 11, a doping region 121 may be formed in the substrate 100. The doping region 121 may be disposed above the substrate 100. The doping region 121 may be disposed on the well region 110. The doping region 121 may contact at least a part of one side surface and a bottom surface of the device isolation layer 400. Source/drain regions 142 and 144, which will be described later, may be formed on the doping region 121.

The doping region 121 may be formed by doping the substrate 100 with an impurity. The doping region 121 may be of a second conductivity type. The doping region 121 may have a different conductivity type than the well region 110. The doping region 121 may be formed by doping the substrate 100 with impurity having the second conductivity type.

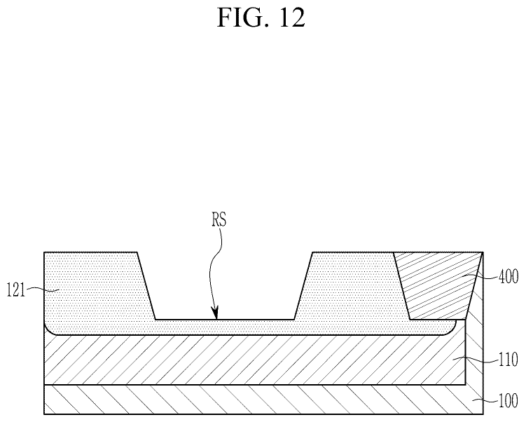

Next, referring to FIG. 12, the recess RS may be formed on the substrate 100. The recess RS may be formed on the doping region 121. During the recess RS formation process, a part of the doping region 121 may be removed. Sidewalls and a bottom surface of the recess RS may be covered by the doping region 121. The recess RS may be formed to be separated from the device isolation layer 400.

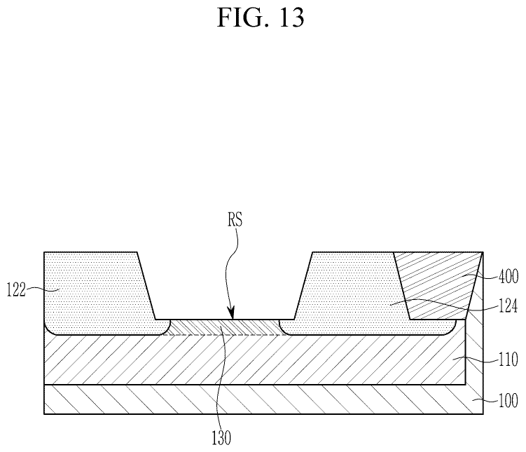

Next, referring to FIG. 13, the channel region 130 may be formed within the substrate 100. As the channel region 130 is formed, the doping region 121 may be divided into the first doping region 122 and the second doping region 124.

The channel region 130 may be disposed between the first doping region 122 and the second doping region 124. The channel region 130 may be disposed on the well region 110.

The channel region 130 may be formed by doping the doping region 121 with an impurity. The channel region 130 may be formed by doping the bottom surface of recess RS with an impurity. For example, the same mask used to form the recess RS in the substrate 100 may be used to form the channel region 130. The mask used to form the recess RS and the mask used to form the channel region 130 may be the same, in which case alignment errors may not occur.

The channel region 130 may have the same conductivity type as the well region 110. The channel region 130 may be of a first conductivity type. The channel region 130 may be formed by doping an impurity having the first conductivity type into the doping region 121. The impurity doping concentration in the channel region 130 may be higher than the impurity doping concentration in the well region 110. When the first conductivity type impurity doping concentration of the channel region 130 is formed relatively high, the effect of reducing leakage current can be expected.

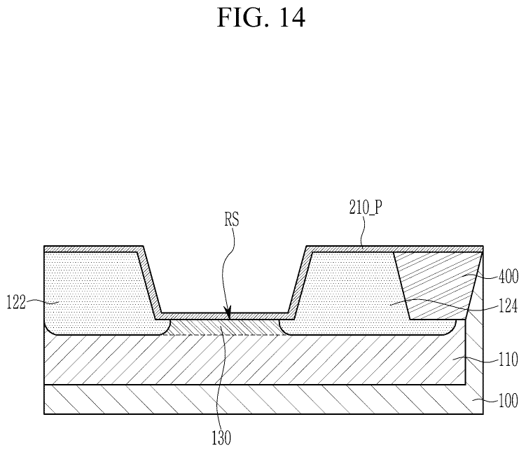

Next, referring to FIG. 14, a first gate insulating material layer 210_P may be formed on the substrate 100. The first gate insulating material layer 210_P may cover the first doping region 122 and the second doping region 124. In addition, the first gate insulating material layer 210_P may cover the device isolation layer 400.

The first gate insulating material layer 210_P may be disposed in the recess RS. The first gate insulating material layer 210_P may cover the sidewall and the bottom surface of the recess RS. The first gate insulating material layer 210_P may contact the upper surface of the channel region 130.

The first gate insulating material layer 210_P may include an insulating material. For example, the first gate insulating material layer 210_P may include at least one of silicon oxide (SiO), silicon nitride (SiN), and silicon oxynitride (SiON).

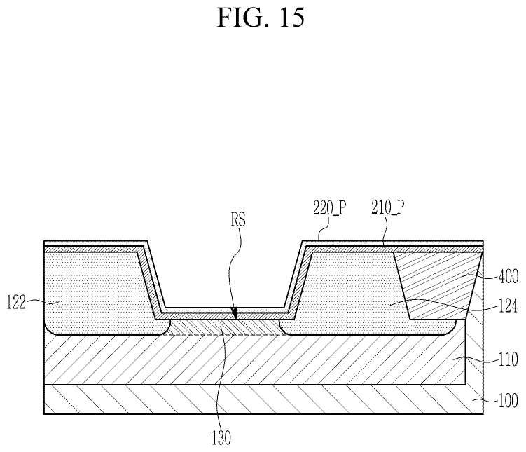

Next, referring to FIG. 15, an intermediate insulating material layer 220_P may be formed on a first gate insulating material layer 210_P.

The intermediate insulating material layer 220_P may include an insulating material. The intermediate insulating material layer 220_P may include a different material from the first gate insulating material layer 210_P. For example, the intermediate insulating material layer 220_P may include at least one of silicon oxide (SiO), silicon nitride (SiN), and silicon oxynitride (SiON).

In some implementations, when the gate insulation layer 200 does not include the intermediate insulation pattern 220 as described above, the process of forming the intermediate insulating material layer 220_P may be omitted.

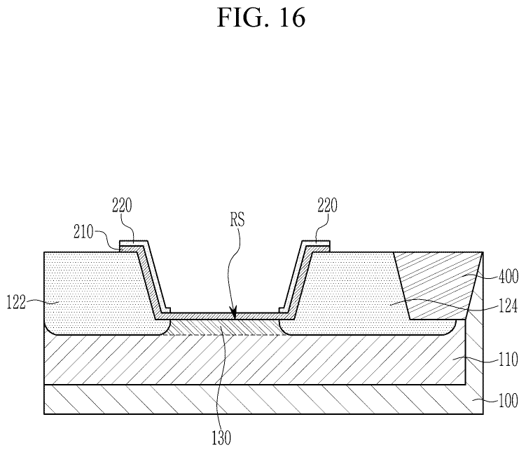

Next, referring to FIG. 16, a patterning process of the first gate insulating material layer 210_P and the intermediate insulating material layer 220_P may be carried out. The first gate insulation pattern 210 may be formed by patterning the first gate insulating material layer 210_P. The intermediate insulation pattern 220 may be formed by patterning the intermediate insulating material layer 220_P.

A portion of the first gate insulating material layer 210_P, disposed on an upper surface of the device isolation layer 400 may be removed. At least a part of the first gate insulating material layer 210_P, disposed on the first doping region 122 and the second doping region 124 may be removed. At least a part of the first gate insulating material layer 210_P, disposed on a bottom surface of the recess RS may be removed. A portion of the first gate insulating material layer 210_P, overlapping an upper surface of the channel region 130 may be removed. As the first gate insulating material layer 210_P is partially removed, the upper surface of the channel region 130 may be removed.

A portion of the intermediate insulating material layer 220_P, disposed on the upper surface of the device isolation layer 400 may be removed. At least a part of the intermediate insulating material layer 220_P, disposed on the first doping region 122 and the second doping region 124 may be removed. A portion of the intermediate insulating material layer 220_P, disposed on the bottom surface of the recess RS may be removed. A portion of the intermediate insulating material layer 220_P, overlapping the upper surface of the channel region 130 may be removed. As the intermediate insulating material layer 220_P is partially removed, the upper surface of the channel region 130 may be exposed.

The first gate insulation pattern 210 and the intermediate insulation pattern 220 may be disposed in the recess RS. The intermediate insulation pattern 220 may be disposed on the first gate insulation pattern 210.

The first gate insulation pattern 210 and the intermediate insulation pattern 220 may be disposed on at least a part of the bottom surface of the recess RS. The first gate insulation pattern 210 and the intermediate insulation pattern 220 may be formed not to overlap the upper surface of the channel region 130. In some implementations, the first gate insulation pattern 210 and the intermediate insulation pattern 220 may be formed to overlap at least a portion of the upper surface of the channel region 130.

The first gate insulation pattern 210 and the intermediate insulation pattern 220 may be disposed on a sidewall of the recess RS. The first gate insulation pattern 210 and the intermediate insulation pattern 220 may be disposed on a sidewall of the first doping region 122 and a sidewall of the second doping region 124. The first gate insulation pattern 210 may be disposed between the intermediate insulation pattern 220 and the sidewall of the recess RS. The first gate insulation pattern 210 may be disposed between the intermediate insulation pattern 220 and the first doping region 122. The first gate insulation pattern 210 may be disposed between the intermediate insulation pattern 220 and the second doping region 124.

The first gate insulation pattern 210 and the intermediate insulation pattern 220 may be disposed on the upper surface of the first doping region 122 and the upper surface of the second doping region 124. However, in some examples, the first gate insulation pattern 210 and the intermediate insulation pattern 220 may be formed not to be disposed on the upper surface of the first doping region 122 and the upper surface of the second doping region 124.

In some implementations, when the intermediate insulating material layer 220_P is not formed, the process of patterning the intermediate insulating material layer 220_P may be omitted.

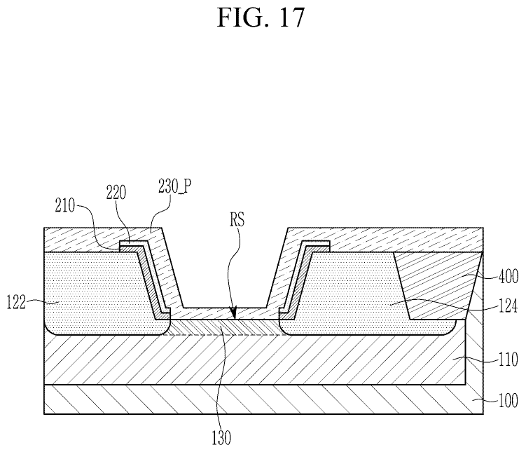

Next, referring to FIG. 17, the second gate insulating material layer 230_P may be formed on the first doping region 122, the second doping region 124, and the sidewall and bottom surface of the recess RS. The second gate insulating material layer 230_P may be formed on the first gate insulation pattern 210 and the intermediate insulation pattern 220. The second gate insulating material layer 230_P may be formed on the upper surface of the channel region 130. The second gate insulating material layer 230_P may be in contact with the upper surface of the channel region 130.

The second gate insulating material layer 230_P may include an insulating material. The second gate insulating material layer 230_P may include the same material as that of the first gate insulating material layer 210_P. For example, the second gate insulating material layer 230_P may include, at least one of silicon oxide (SiO), silicon nitride (SiN), and silicon oxynitride (SiON).

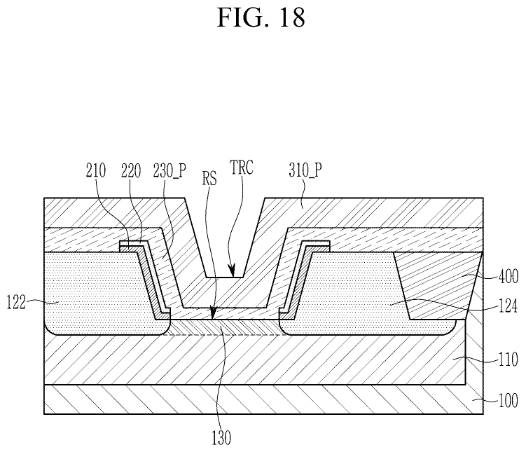

Next, referring to FIG. 18, the gate electrode material layer 310_P may be formed on the second gate insulating material layer 230_P. The gate electrode material layer 310_P may be disposed on the first doping region 122 and the second doping region 124. The gate electrode material layer 310_P may be disposed in the recess RS. The gate electrode material layer 310_P may be disposed on the sidewall and the bottom surface of the recess RS.

As the gate electrode material layer 310_P is formed in the recess RS, the trench TRC may be formed in the gate electrode material layer 310_P. However, in some example, the gate electrode material layer 310_P may also be filled in the trench TRC formed in the gate electrode material layer 310_P. Accordingly, there may be no trench TRC above the gate electrode 310.

The gate electrode material layer 310_P may include a conductive material. For example, the gate electrode material layer 310_P may include doped polysilicon. Alternatively, the gate electrode material layer 310_P for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. The gate electrode material layer 310_P may include a conductive metal oxide, conductive metal oxynitride, and the like, and may include the material described above in an oxidized form.

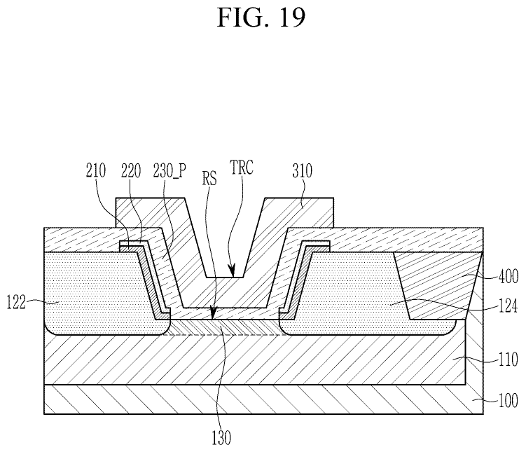

Next, referring to FIG. 19, the gate electrode material layer 310_P may be patterned. The gate electrode material layer 310_P is patterned such that the gate electrode 310 can be formed. A part of the gate electrode material layer 310_P, disposed on the first doping region 122 may be removed. A part of the gate electrode material layer 310_P, disposed on the second doping region 124 may be removed.

In some example, the gate electrode material layer 310_P may be formed not to be disposed on the first doping region 122 and the second doping region 124. In addition, in order to form the spacer 320 between the gate electrode 310 and the second gate insulation pattern 230, additional patterning may be carried out on the gate electrode material layer 310_P and the second gate insulating material layer 230_P.

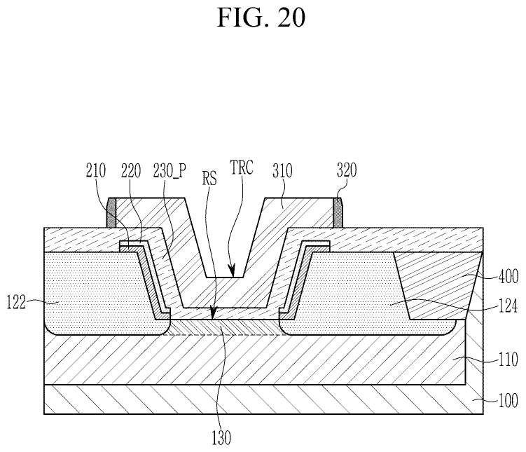

Next, referring to FIG. 20, the spacer 320 may be formed at opposite sides of the gate electrode 310. The spacer 320 may be disposed on the first doping region 122 and the second doping region 124. The spacer 320 may be disposed on the second gate insulating material layer 230_P.

In some examples, the spacer 320 may be additionally formed in the trench TRC formed in the gate electrode 310.

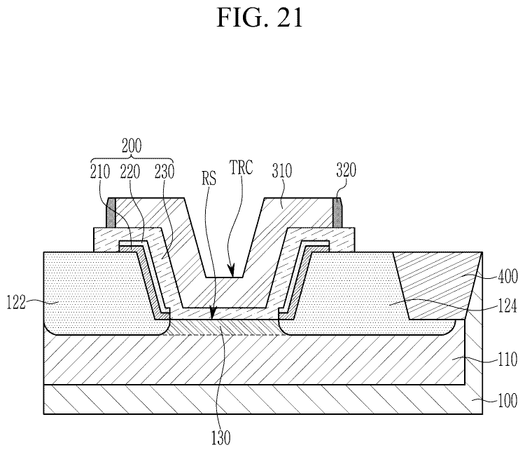

Next, referring to FIG. 21, a process of patterning second gate insulating material layer 230_P may be performed. The second gate insulating material layer 230_P is patterned to form the second gate insulation pattern 230. A part of the second gate insulating material layer 230_P, disposed on the first doping region 122 and the second doping region 124 may be removed.

A part of the second gate insulating material layer 230_P is removed such that a part of the upper surfaces of the first doping region 122 and a part of the second doping region 124 may be exposed. For example, a mask used for patterning the second gate insulating material layer 230_P may be the same as a mask used for forming the first source/drain region 142 and the second source/drain region 144, which will be described later.

The second gate insulation pattern 230 may be disposed on a part of the first doping region 122 and a part of the second doping region 124.

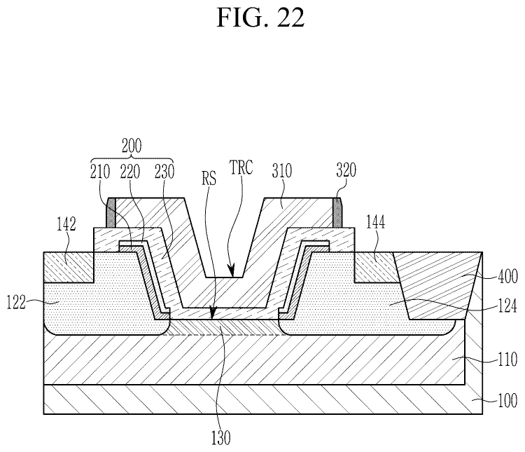

Next, referring to FIG. 22, the first source/drain region 142 and the second source/drain region 144 may be formed in the substrate 100.

For example, a mask used during a process for forming the first source/drain region 142 and the second source/drain region 144 may be the same mask used for forming the second gate insulation pattern 230.

The first source/drain region 142 and the second source/drain region 144 may be formed on the well region 110. The first source/drain region 142 may be formed on the first doping region 122. The second source/drain region 144 may be formed on the second doping region 124. The bottom surface and at least part of the side surface of the first source/drain region 142 may be surrounded by the first doping region 122. The bottom surface and at least part of the side surface of the second source/drain region 144 may be surrounded by the second doping region 124.

The first source/drain region 142 may be formed by doping an impurity on the first doping region 122. The second source/drain region 144 may be formed by doping an impurity on the second doping region 124.

The first source/drain region 142 and the second source/drain region 144 may be of a second conductivity type. The first source/drain region 142 and the second source/drain region 144 may have different conductivity types from a conductivity type of the well region 110. The first source/drain region 142 and the second source/drain region 144 may have the same conductivity type as the conductivity type of the first doping region 122 and the second doping region 124. The impurity doping concentrations of the first source/drain region 142 and the second source/drain region 144 may be higher than the impurity doping concentrations of the first doping region 122 and the second doping region 124.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with what is presently considered to be practical examples, it is to be understood that the invention is not limited to the disclosed examples. On the contrary, it is intended to cover various modifications and equivalent arrangements included within the spirit and scope of the appended claims.

What is claimed is:

1. A semiconductor device comprising:
a well region of a first conductivity type in a substrate;
a first doping region of a second conductivity type and a second doping region of the second conductivity type, the first doping region and the second doping region being on the well region;
a first source/drain region on the first doping region and a second source/drain region on the second doping region;
a gate insulation layer including (i) a first gate insulation pattern that covers a sidewall of a recess defined between the first doping region and the second doping region and (ii) a second gate insulation pattern on the first gate insulation pattern;
a gate electrode on the gate insulation layer; and
a channel region below the gate insulation layer.

2. The semiconductor device of claim 1, comprising a device isolation layer at a side of the well region, and
wherein the second doping region covers a side surface of the device isolation layer and at least a portion of a bottom surface of the device isolation layer.

3. The semiconductor device of claim 1, wherein the first gate insulation pattern is offset from a center portion of a bottom surface of the recess.

4. The semiconductor device of claim 1, wherein the channel region is of the first conductivity type, and
wherein doping concentration of the channel region is greater than doping concentration of the well region.

5. The semiconductor device of claim 1, wherein the channel region is on the well region between the first doping region and the second doping region.

6. The semiconductor device of claim 1, wherein the first gate insulation pattern is in contact with the first doping region and the second doping region.

7. The semiconductor device of claim 1, comprising an intermediate insulation pattern between the first gate insulation pattern and the second gate insulation pattern.

8. The semiconductor device of claim 7, wherein the intermediate insulation pattern is offset from an upper surface of the channel region.

9. The semiconductor device of claim 7, wherein the intermediate insulation pattern comprises a material that is different from (i) a material of the first gate insulation pattern and (ii) a material of the second gate insulation pattern.

10. The semiconductor device of claim 1, wherein the first source/drain region and the second source/drain region are of the second conductivity type, and
wherein each of a doping concentration of the first source/drain region and doping concentration of the second source/drain region is greater than each of doping concentration of the first doping region and doping concentration of the second doping region, respectively.

11. A semiconductor device comprising:
a well region of a first conductivity type at a substrate;
a first doping region of a second conductivity type and a second doping region of the second conductivity type, the first doping region and the second doping region being on the well region;
a first source/drain region on the first doping region and a second source/drain region on the second doping region;
a gate insulation layer including (i) a first gate insulation pattern that covers a sidewall of a recess defined between the first doping region and the second doping region and (ii) a second gate insulation pattern on the first gate insulation pattern;
a gate electrode on the gate insulation layer and overlapping (i) an upper surface of the first doping region and (ii) an upper surface of the second doping region;
a channel region below the gate insulation layer; and
a first spacer at a first side of the gate electrode and on the second gate insulation pattern, and a second spacer at a second side of the gate electrode and on the second gate insulation pattern.

12. The semiconductor device of claim 11, comprising an intermediate insulation pattern between the first gate insulation pattern and the second gate insulation pattern.

13. The semiconductor device of claim 12, wherein the intermediate insulation pattern is offset from an upper surface of the channel region.

14. The semiconductor device of claim 11, wherein the first gate insulation pattern is offset from a center portion of a bottom surface of the recess.

15. The semiconductor device of claim 11, wherein the channel region is of the first conductivity type, and
wherein doping concentration of the channel region is greater than doping concentration of the well region.

16. A semiconductor device comprising:
a well region of a first conductivity type in a substrate;
a first doping region and a second doping region of a second conductivity type on the well region;
a first source/drain region on the first doping region and a second source/drain region on the second doping region;
a gate insulation layer including (i) a first gate insulation pattern that covers a sidewall of a recess defined between the first doping region and the second doping region and (ii) a second gate insulation pattern on the first gate insulation pattern;
a gate electrode on the gate insulation layer and overlapping (i) an upper surface of the first doping region and (ii) an upper surface of the second doping region;
a channel region below the gate insulation layer; and
a first spacer at a first side of the gate electrode and on the second gate insulation pattern, and a second spacer at a second side of the gate electrode and on the second gate insulation pattern.

17. The semiconductor device of claim 16, comprising an intermediate insulation pattern between the first gate insulation pattern and the second gate insulation pattern.

18. The semiconductor device of claim 17, wherein the intermediate insulation pattern is offset from an upper surface of the channel region.

19. The semiconductor device of claim 16, wherein the first gate insulation pattern is offset from a center portion of a bottom surface of the recess.

20. The semiconductor device of claim 16, wherein the channel region is of the first conductivity type, and a doping concentration of the channel region is greater than doping concentration of the well region.
